(19) United States
(12) Patent Application Publication
(10) Pub. No.: US 2014/0251423 A1
(43) Pub. Date: Sep. 11, 2014

(54) SOLAR CELL AND METHOD OF MANUFACTURING THE SAME

(71) Applicant: LG ELECTRONICS INC., Seoul (KR)

(72) Inventors: Younghyun LEE, Seoul (KR); Sangwook PARK, Seoul (KR); Yoonsil JIN, Seoul (KR)

(73) Assignee: LG ELECTRONICS INC., Seoul (KR)

(21) Appl. No.: 14/198,069

(22) Filed: Mar. 5, 2014

(30) Foreign Application Priority Data
Mar. 6, 2013 (KR) 10-2013-0024081

(51) Int. Cl. H01L 31/0224

(52) U.S. Cl. CPC H01L 31/022425
USPC 136/256; 438/98

(57) ABSTRACT

A solar cell and a method of manufacturing the same are disclosed. The solar cell includes a substrate, a conductive type region formed at the substrate, an insulating film formed on the conductive type region, and an electrode electrically connected to the conductive type region through openings formed in the insulating film. The electrode includes finger electrodes and at least one bus bar electrode formed in a direction crossing the finger electrodes. The bus bar electrode includes electrode parts separated from each other. The insulating film includes a plurality of openings corresponding to the electrode parts to be exposed between the electrode parts at a portion at which the bus bar electrode is disposed. The electrode parts include seed layers electrically connected to the conductive type region via the openings of the insulating film and plating layers disposed on the seed layers and the insulating film.

### CROSS-REFERENCE TO RELATED APPLICATION

This application claims the priority benefit of Korean Patent Application No. 10-2013-0024081, filed on Mar. 6, 2013 in the Korean Intellectual Property Office, the disclosure of which is incorporated herein by reference.

### BACKGROUND

1. Field

Embodiments relate to a solar cell and a method of manufacturing the same, and more particularly to a solar cell having an improved electrode structure and a method of manufacturing the same.

2. Description of the Related Art

Recently, as existing energy resources such as petroleum and coal are running out, interest in alternative energy sources is increasing. In particular, solar cells, which directly convert solar energy into electric energy, are receiving much attention as a next-generation battery.

Such solar cells include various layers, electrodes, and the like formed on a substrate according to design, and adjacent solar cells are electrically connected by ribbons. In this regard, bus bar electrodes of adjacent solar cells are electrically connected using a ribbon, and the bus bar electrodes have a relatively large width so as to correspond to the width of a ribbon in consideration of electrical characteristics. Accordingly, the amount of materials for fabricating an electrode increases and thus manufacturing costs are increased.

In addition, a process of electrically connecting adjacent solar cells using a ribbon operates at a high temperature and thus thermal impact may be applied to the solar cells during the process. To prevent this, a method of using conductive films instead of ribbons has been proposed. However, in this method, adhesion between an electrode and a substrate is poor and thus the electrode may be separated from the substrate after adhesion of a conductive film.

### SUMMARY

Embodiments provide a solar cell that may provide an enhanced connection between adjacent solar cells and enhanced productivity and a method of manufacturing the same.

In one embodiment, a solar cell includes a substrate, a conductive type region formed at the substrate, an insulating film formed on the conductive type region, and an electrode electrically connected to the conductive type region through the insulating film. The electrode includes a plurality of finger electrodes and at least one bus bar electrode formed in a direction crossing the finger electrodes. The bus bar electrode includes a plurality of electrode parts separated from each other. The insulating film includes a plurality of openings corresponding to the electrode parts to be exposed between the electrode parts at a portion at which the bus bar electrode is disposed. The electrode parts may include seed layers electrically connected to the conductive type region via the openings of the insulating film and plating layers disposed on the seed layers and the insulating film.

In another embodiment, a solar cell includes a substrate, a conductive type region formed at the substrate, an insulating film formed on the conductive type region, and an electrode electrically connected to the conductive type region via openings formed in the insulating film. The electrode includes a plurality of finger electrodes arranged in parallel in a first direction and at least one bus bar electrode formed in a second direction crossing the first direction. The bus bar electrode includes a plurality of electrode parts separated from each other so as to expose the insulating film. Each of the electrode parts may have a width of 30 μm to 45 μm, and a pitch between the electrode parts may be 50 μm to 200 μm.

In another embodiment, a method of manufacturing a solar cell includes preparing a substrate, forming a conductive type region at the substrate, forming an insulating film on the conductive type region, forming a plurality of openings separated from each other in the insulating film to correspond to a bus bar electrode, and forming the bus bar electrode by forming a plurality of electrode parts electrically connected to the conductive type region via the openings formed in the insulating film. The insulating film is exposed between the electrode parts.

### BRIEF DESCRIPTION OF THE DRAWINGS

Details of the embodiments will be more clearly understood from the following detailed description taken in conjunction with the accompanying drawings, in which:

FIG. 1 is an exploded perspective view of a solar cell module according to an embodiment of the present invention;

FIG. 2 is a schematic sectional view taken along line II-II of FIG. 1;

FIG. 3 is a partial sectional view illustrating solar cells included in the solar cell module according the embodiment of the present invention;

FIG. 4 is a schematic plan view of a front surface of the solar cell of FIG. 3;

FIG. 5 is a graph showing measurement results of peel strength between an electrode and a conductive film and peel strength between an anti-reflective film formed of silicon nitride and the conductive film;

FIGS. 6A to 6E are sectional views illustrating a solar cell manufacturing method according to an embodiment of the present invention; and

FIG. 7 is a sectional view of a solar cell according to another embodiment of the present invention.

### DETAILED DESCRIPTION OF EMBODIMENTS

Reference will now be made in detail to embodiments, examples of which are illustrated in the accompanying drawings. However, the present disclosure may be embodied in many different forms and should not be construed as limited to the embodiments set forth herein.

Only elements constituting essential features of the present invention are illustrated in the accompanying drawings and other non-essential elements that will not be described herein are omitted from the drawings, for clarity of description. Like reference numerals refer to like elements throughout. In the drawings, the thicknesses, areas, etc. of constituent elements may be exaggerated or reduced for clarity and convenience of illustration. The present invention is not limited to the illustrated thicknesses, areas, etc.

It will be further understood that, throughout this specification, when one element is referred to as “comprising” another element, the term “comprising” specifies the presence of another element but does not preclude the presence of other additional elements, unless context clearly indicates otherwise. In addition, it will be understood that when one element such as a layer, a film, a region or a plate is referred to as being “on” another element, the one element may be directly on the another element, and one or more intervening elements may also be present. In contrast, when one element such as a layer, a film, a region or a plate is referred to as being “directly on” another element, no intervening elements are present.

Hereinafter, a solar cell according to an embodiment of the present invention and a method of manufacturing the same will be described in detail with reference to the accompanying drawings.

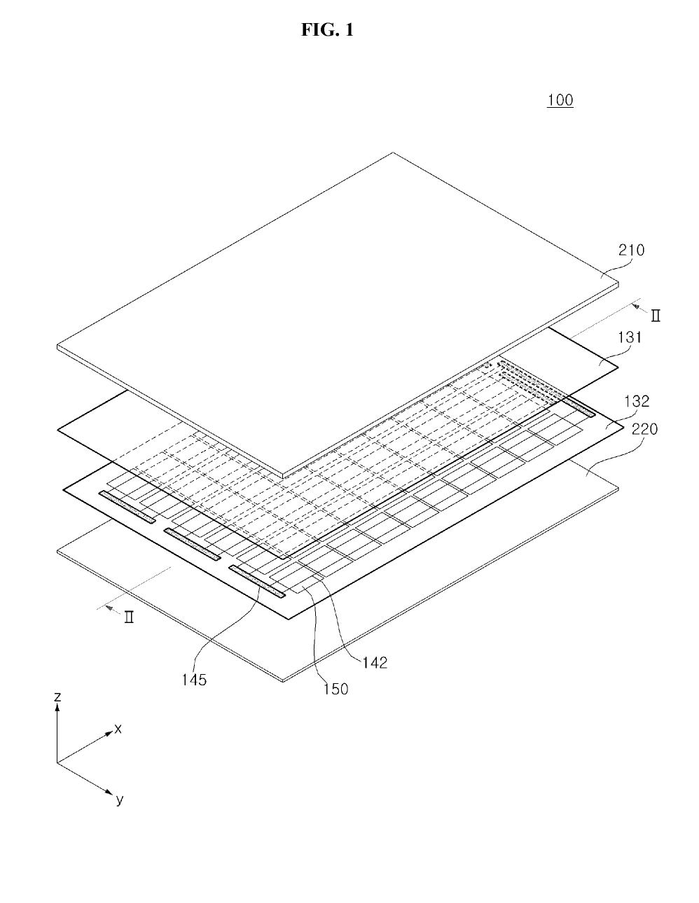

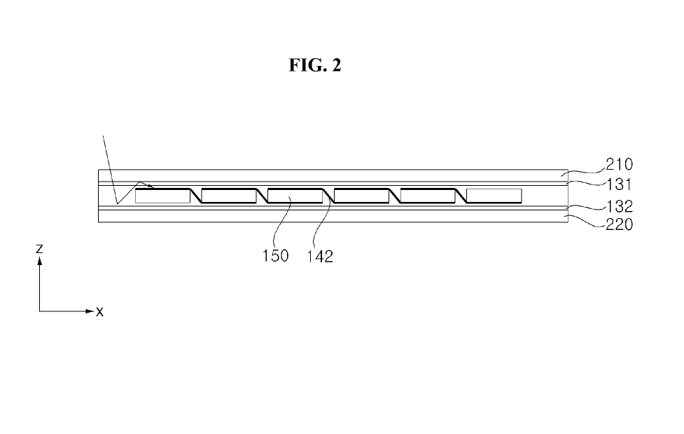

FIG. 1 is an exploded perspective view of a solar cell module 100 according to an embodiment of the present invention. FIG. 2 is a schematic sectional view taken along line II-II of FIG. 1.

Referring to FIGS. 1 and 2, the solar cell module 100 according to the present embodiment may include solar cells 150, a front substrate 210 disposed on front surfaces of the solar cells 150, and a back sheet 220 disposed on back surfaces of the solar cells 150. In addition, the solar cell module 100 may include a first sealant 131 disposed between the solar cells 150 and the front substrate 210 and a second sealant 132 disposed between the solar cells 150 and the back sheet 220.

The solar cells 150 are semiconductor devices that convert solar energy into electric energy and examples thereof include, but are not limited to, a silicon solar cell, a compound semiconductor solar cell, a tandem solar cell, and a dye-sensitized solar cell.

The solar cells 150 include a conductive film 142 to electrically connect the solar cells 150 in series, in parallel, or in series-parallel. In particular, the conductive film 142 may connect a first electrode formed on a light-receiving surface of one of the solar cells 150 to a second electrode formed on an opposite surface of another of the solar cells 150 adjacent to the one. That is, the conductive film 142 may be positioned on surfaces of the solar cells 150 and subjected to heat pressing to connect the solar cells 150 in series or in parallel. The conductive film 142 may be formed by dispersing conductive particles formed of gold (Au), silver (Ag), nickel (Ni), copper (Cu), or the like, which are highly conductive, in a film formed of epoxy resin, acryl resin, polyimide resin, polycarbonate resin, or the like. When the conductive film 142 is thermally pressed, the conductive particles are exposed outside of the film and the solar cells 150 and the conductive film 142 may be electrically connected by the exposed conductive particles. As such, when a solar cell module is manufactured by connecting the solar cells 150 by the conductive film 142, manufacturing temperature may be reduced and thus bending of the solar cells 150 may be prevented.

In addition, bus ribbons 145 alternately connect opposite ends of a row of the solar cells 150 connected by the conductive film 142. The bus ribbons 145 may be arranged in a direction crossing ends of a row of the solar cells 150. The bus ribbons 145 are connected to a junction box (not shown) that collects electricity produced by the solar cells 150 and prevents reverse flow of electricity.

The first sealant 131 may be disposed on light-receiving surfaces of the solar cells 150, and the second sealant 132 may be disposed on opposite surfaces of the solar cells 150. The first and second sealants 131 and 132 are adhered by lamination and thus prevent permeation of moisture or oxygen that may adversely affect the solar cells 150 and enable chemical bonding of the elements of the solar cells 150.

The first and second sealants 131 and 132 may be formed using ethylene vinyl acetate (EVA) copolymer resin, polyvinyl butyral, a silicon resin, an ester-based resin, an olefin-based resin, or the like, but the disclosure is not limited thereto. Thus, the first and second sealants 131 and 132 may be formed using various other materials by various methods other than lamination.

The front substrate 210 is disposed on the first sealant 131 so as to pass sunlight therethrough and may be made of tempered glass to protect the solar cells 150 from external impact and the like. In addition, the front substrate 210 may be made of low-iron tempered glass to prevent reflection of sunlight and increase transmittance of sunlight.

The back sheet 220 is disposed on opposite surfaces of the solar cells 150 to protect the solar cells 150 and is waterproof and insulating and blocks ultraviolet light. The back sheet 220 may be of a Tedlar/PET/Tedlar (TPT) type, but the disclosure is not limited thereto. In addition, the back sheet 220 may be made of a material with excellent reflectance so as to reflect sunlight incident from the front substrate 210 and for the sunlight to be reused, but the disclosure is not limited thereto. That is, the back sheet 220 may be made of a transparent material so that sunlight is incident thereupon and thus the solar cell module 100 may be embodied as a double-sided solar cell module.

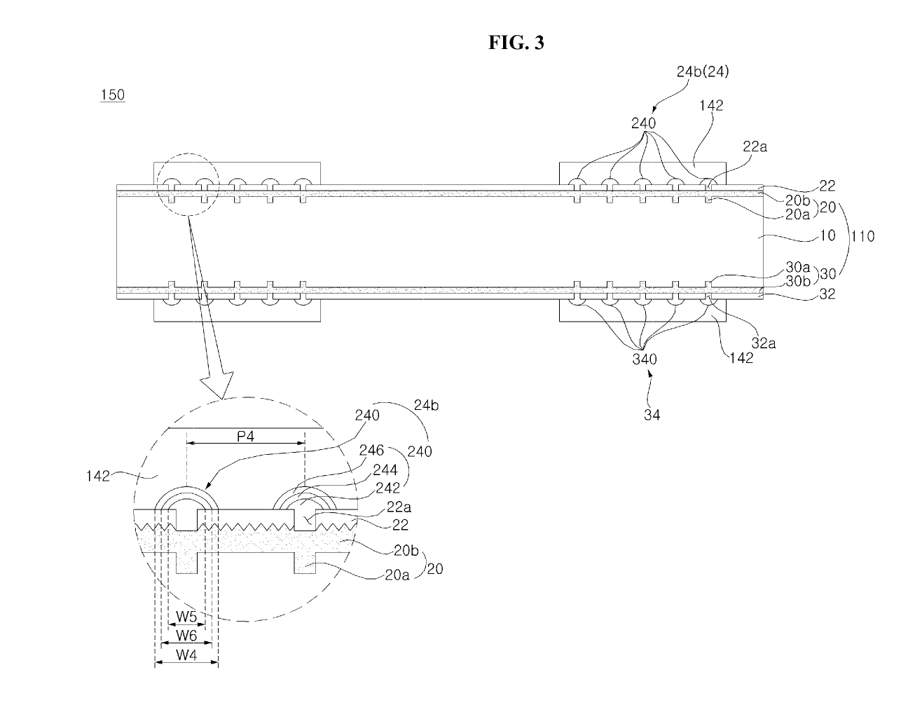

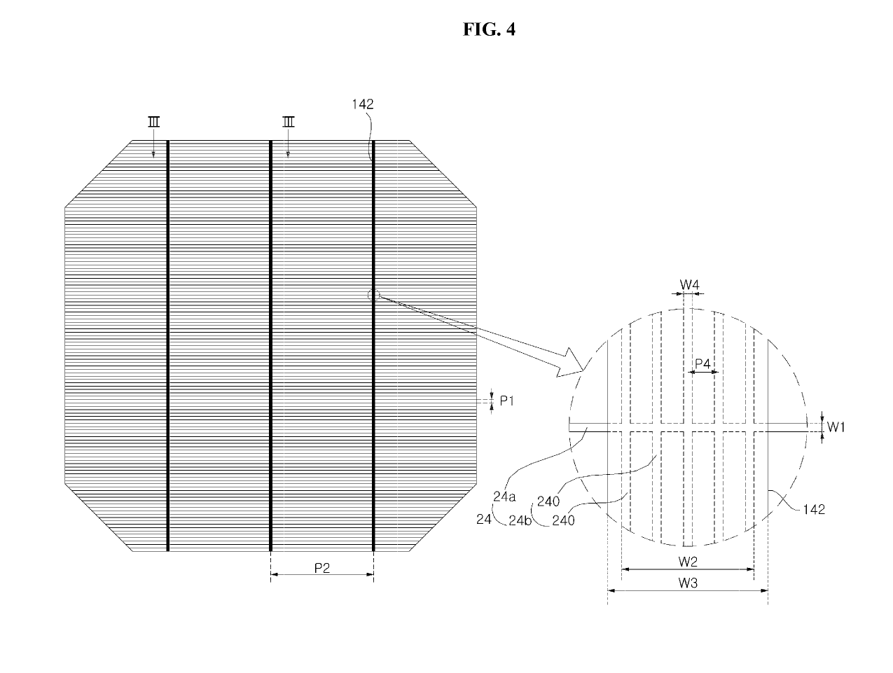

Hereinafter, the solar cell 150 according to the embodiment of the present invention will be described in more detail. FIG. 3 is a partial sectional view of the solar cells 150 included in the solar cell module 100 according to the embodiment of the present invention. FIG. 4 is a schematic plan view illustrating front surfaces of the solar cells 150 of FIG. 3. For reference, FIG. 3 is a sectional view taken along line III-III of FIG. 4.

Referring to FIG. 3, the solar cell 150 according to the present embodiment may include a semiconductor substrate 110, conductive type regions 20 and 30 formed at the semiconductor substrate 110, insulating films 22 and 32 respectively formed on the conductive type regions 20 and 30, and electrodes 24 and 34 respectively formed on the insulating films 22 and 32 to be electrically connected respectively to the conductive type regions 20 and 30. The conductive type regions 20 and 30 may include an emitter region 20 and a back surface field region 30, and the insulating films 22 and 32 may include an anti-reflective film 22 and a passivation film 32. The electrodes 24 and 34 may include a first electrode 24 electrically connected to the emitter region 20 and a second electrode 34 electrically connected to the back surface field region 30. In addition, the conductive film 142 electrically connected to each of the electrodes 24 and 34 may be disposed on each of the electrodes 24 and 34 to connect adjacent solar cells 150 to each other. This will be described below in more detail.

The semiconductor substrate 110 includes an area in which the conductive type regions 20 and 30 are formed and a region in which the conductive regions 20 and 30 are not formed, i.e., a base region 10. The base region 10 may include, for example, silicon including a second conductive type impurity. The silicon may be mono-crystalline silicon or polycrystalline silicon, and the second conductive type impurity may for example be of an n-type. That is, the base region 10 may be formed of mono-crystalline or polycrystalline silicon doped with a Group V element such as phosphorus (P), arsenic (As), bismuth (Bi), antimony (Sb), or the like.

As such, when the base region 10 having an n-type impurity is used, the emitter region 20 having a p-type impurity is formed at a first surface (hereinafter referred to as a “front surface”) of the semiconductor substrate 110, thereby forming a pn junction. When the pn junction is irradiated with light, electrons generated by photoelectric effects migrate towards a second surface (hereinafter referred to as a “back surface”) of the semiconductor substrate 110 and are collected by the second electrode 34, and holes migrate towards the front surface of the semiconductor substrate 110 and are collected by the first electrode 24. Accordingly, electric energy is generated. In this regard, holes having a slower movement rate than electrons migrate towards the front of the semiconductor substrate 110 instead of the back surface thereof and, accordingly, conversion efficiency may be enhanced.

However, the disclosure is not limited to the above examples and the semiconductor substrate 110 and the back surface field region 30 may be of a p-type and the emitter region 20 may be of an n-type.

As illustrated in an enlarged circle of FIG. 3, at least one of the front and back surfaces of the semiconductor substrate 110 may be textured to have an uneven portion in the form of a pyramid, or the like. Through the texturing process, the uneven portion is formed at the front surface of the semiconductor substrate 110 and thus surface roughness thereof increases, whereby reflectance of light incident upon the front surface of the semiconductor substrate 110 may be reduced. Accordingly, the amount of light reaching a pn junction formed at an interface between the semiconductor substrate 110 and the emitter region 20 may be increased and, consequently, light loss may be minimized. However, in the present embodiment, portions of the semiconductor substrate 110 corresponding to openings 22a of the anti-reflective film 22 and openings 32a of the passivation film 32 may not have an uneven portion formed by texturing. This will be described below in more detail.

The emitter region 20 having a first conductive type impurity may be formed at the front surface of the semiconductor substrate 110. In the present embodiment, the first conductive type impurity of the emitter region may be a p-type impurity, for example, a Group III element such as boron (B), aluminum (Al), gallium (Ga), indium (In), or the like.

In the present embodiment, the emitter region 20 may have a first portion 20a having a high impurity concentration thus having a relatively low resistance and a second portion 20b having a lower impurity concentration than the first portions 20a thus having a relatively high resistance. In this regard, the first portion 20a may include a plurality of first portions 20a separated from each other to correspond to a plurality of electrode parts 240 constituting the first electrode 24 at portions of the first electrode 24 contacting the first portions 20a. This will be described below in further detail.

As such, in the present embodiment, the second portion 20b, having a relatively high resistance, is formed in a portion corresponding to a region between the first electrodes 24 upon which light is incident, thereby forming a shallow emitter. Accordingly, current density of the solar cells 150 may be enhanced. In addition, the first portions 20a, having a relatively low resistance, are formed adjacent to the first electrode 24 (in particular, the electrode parts 240 constituting the first electrode 24) and thus contact resistance with the first electrode 24 may be reduced. That is, the emitter region according to the present embodiment may maximize efficiency of the solar cells 150 by the selective emitter structure.

The anti-reflective film 22 and the first electrode are formed on the semiconductor substrate 110, more particularly on the emitter region 20 formed at the semiconductor substrate 110.

The anti-reflective film 22 may be formed over substantially the entire front surface of the semiconductor substrate 110, not on a portion corresponding to the first electrode 24. The anti-reflective film 22 reduces reflectance of light incident upon the front surface of the semiconductor substrate 110 and inactivates defects present at the surface or bulk of the emitter region 20.

The amount of light reaching the pn junction formed at the interface between the semiconductor substrate 110 and the emitter region 20 may be increased by reducing the reflectance of light incident through the front surface of the semiconductor substrate 110. Accordingly, short-circuit current Isc of the solar cells 150 may be increased. In addition, an open circuit voltage Voc of the solar cells 150 may be increased by removing recombination sites of minority carriers through inactivation of defects present in the emitter region 20. As such, efficiency of the solar cells 150 may be enhanced by increasing the open circuit voltage Voc and short-circuit current Isc of the solar cells 150 by the anti-reflective film 22.

The anti-reflective film 22 may be formed of various materials. For example, the anti-reflective film 22 may be any one film selected from the group consisting of a silicon nitride film, a hydrogen-containing silicon nitride film, a silicon oxide film, a silicon oxynitride film, an aluminum oxide film, a MgF₂ film, a ZnS film, a TiO₂ film, and a CeO₂ film or have a multilayer structure including two or more of the above-listed films in combination. However, the disclosure is not limited to the above examples and the anti-reflective film 22 may include various other materials. In addition, a separate front surface passivation film (not shown) that serves to passivate may further be formed between the semiconductor substrate 110 and the anti-reflective film 22. This is also within the scope of the present invention.

The first electrode 24 is electrically connected to the emitter region 20 via the openings 22a formed in the anti-reflective film 22 (i.e., through the anti-reflective film 22). The first electrode 24 may be formed of various materials so as to have various shapes. This will be described below in detail.

The back surface field region 30 including a second conductive type impurity at a higher doping concentration than the semiconductor substrate 110 is formed at the back surface of the semiconductor substrate 110. In the present embodiment, the back surface field region 30 may use an n-type impurity as the second conductive type impurity, for example, a Group V element such as P, As, Bi, Sb, or the like.

In addition, in the present embodiment, the back surface field region 30 may have a first portion 30a having a high impurity concentration, thus having a relatively low resistance, and a second portion 30b having a low impurity concentration, thus having a relatively high resistance. In this regard, the first portion 30a may include a plurality of first portions 30a separated from each other to correspond to a plurality of electrode parts 340 constituting the second electrode 34 at portions of the second electrode 34 contacting the first portions 30a. This will be described below in further detail. As such, in the present embodiment, the second portion 30b having a relatively high resistance is formed in a portion corresponding to a region between the second electrodes 34 and thus recombination between holes and electrons may be prevented. Accordingly, current density of the solar cell 150 may be enhanced. In addition, the first portion 30a having a relatively low resistance is formed in a portion adjacent to the second electrode 34 (in particular, the electrode parts 340 constituting the second electrode 34) and thus contact resistance with the second electrode 34 may be reduced. That is, the back surface field region 30 according to the present embodiment may maximize efficiency of the solar cell 150 by a selective back surface field structure.

However, the disclosure is not limited to the above examples and the back surface field regions 30 may have a local back surface field structure locally formed only at a portion of the back surface of the semiconductor substrate 110 contacting the second electrode 34 (in particular, the electrode parts 340 constituting the second electrode 34). That is, the back surface field region 30 may include only the first portions 30a locally formed only at portions corresponding to the electrode parts 340 of the second electrode 34.

In the above-described embodiment, both the emitter region 20 and the back surface field region 30 have a selective structure. However, the disclosure is not limited to the above examples and only any one of the emitter region 20 and the back surface field region 30 may have a selective structure.

In addition, the passivation film 32 and the second electrode 34 may be formed on the back surface of the semiconductor substrate 110.

The passivation film 32 may be formed substantially over the entire back surface of the semiconductor substrate 110, not on a portion in which the second electrode 34 is formed. The passivation film 32 may remove recombination sites of minority carriers by inactivating defects present in the back surface of the semiconductor substrate 110. Accordingly, the open circuit voltage of the solar cell 150 may be increased.

The passivation film 32 may be formed of a transparent insulating material so as to pass light therethrough. Thus, light may be incident through the back surface of the semiconductor substrate 110 by the passivation film 32 and, accordingly, efficiency of the solar cell 150 may be enhanced. For example, the passivation film 32 may be any one film selected from the group consisting of a silicon nitride film, a hydrogen-containing silicon nitride film, a silicon oxide film, a silicon oxynitride film, an aluminum oxide film, a MgF₂ film, a ZnS film, a TiO₂ film, and a CeO₂ film or have a multilayer structure including two or more of the above-listed films in combination. However, the disclosure is not limited to the above examples and the passivation film 32 may include various other materials.

The second electrode 34 is electrically connected to the back surface field region 30 via the openings 32a formed in the passivation film 32 (i.e., through the passivation film 32). The second electrode 34 may be formed of various materials so as to have various shapes.

In this regard, the first electrode 24 and/or the second electrode 34 according to the present embodiment may have a structure that allows enhancement of adhesion to or connection with the semiconductor substrate 110. An example thereof will be described with reference to FIGS. 3 and 4. The first and second electrodes 24 and 34 may have different widths, pitches, and the like, while having similar basic shapes. In this regard, only the first electrode 24 will be described with reference to FIG. 4 and a detailed description of the second electrode 34 will be omitted herein. The following description may be equally applied to the first and second electrodes 24 and 34.

Referring to FIG. 4, as seen in a plan view, the first electrode 24 may include a plurality of finger electrodes 24a having a first pitch P1 and arranged in parallel. In addition, the first electrode 24 may include a bus bar electrode 24b formed in a direction crossing the finger electrodes 24a to connect the finger electrodes 24a. In this regard, a single bus bar electrode 24b may be formed and, as illustrated in FIG. 4, a plurality of bus bar electrodes 24b having a second pitch P2 that is larger than the first pitch P1 may be formed. In this regard, an outer width W2 of the bus bar electrode 24b may be larger than a width W1 of the finger electrode 24a, but the disclosure is not limited thereto. The shape of the first electrode 24 is provided for illustrative purposes only, and the disclosure is not limited to the above example.

In the present embodiment, the bus bar electrode 24b may be provided inside thereof with an exposed region so as to expose the anti-reflective film 22 (the passivation film 32 in the case of the second electrode 34), which is an insulating film. For example, the bus bar electrode 24b may include the electrode parts 240 separated from each other so as to expose the anti-reflective film 22 between the electrode parts 240. In this regard, the electrode parts 240 adhered to the conductive film 142 are defined as a plurality of electrode parts 240 constituting the bus bar electrode 24b. In the following description, the outer width W2 of the bus bar electrode 24b is defined as a distance between outer edges of outermost two of the electrode parts 240 constituting the bus bar electrode 24b. In addition, an outer area of the bus bar electrode 24b means a sum of an area of the outermost two of the electrode parts 240 constituting the bus bar electrode 24b and an area of another of the electrode parts 240 disposed between the outermost two.

Hereinafter, a relationship among the electrode parts 240 constituting the bus bar electrode 24b, the openings 22a formed in the anti-reflective film 22, and the first portions 20a of the emitter region 20 will be described with reference to FIG. 3. Thereafter, a planar shape, stacked structure, and the like of the electrode parts 240 constituting the bus bar electrode 24b will be described in detail.

Referring to FIG. 3, in the present embodiment, the electrode parts 240 constituting the bus bar electrode 24b, the openings 22a formed in the anti-reflective film 22, and the first portions 20a of the emitter region 20 are formed at corresponding positions. That is, the electrode part 240 is disposed in each of the openings 22a formed in the anti-reflective film 22, and a portion of the emitter region 20 contacting each electrode part 240 via each opening 22a constitutes the first portion 20a. Accordingly, the openings 22a of the anti-reflective film 22 and the first portions 20a of the emitter region 20 are partially disposed to correspond to the bus bar electrode 24b. Thus, the anti-reflective film 22 remains and the second portion 20b of the emitter region 20 is disposed even at a portion at which the bus bar electrode 24b and the conductive film 142 are adhered to each other.

For example, as illustrated in FIG. 4, in the present embodiment, the openings 22a of the anti-reflective film have a line shape and thus the openings 22a corresponding to the bus bar electrode 24b may have a stripe shape. Such configuration is intended to simplify manufacturing processes and decrease manufacturing time. In the present embodiment, the openings 22a of the anti-reflective film 22 may be formed by laser ablation. In laser ablation, a movement rate of a laser needs to be reduced when changing a movement direction of the laser. Thus, when the openings 22 are formed so as to have a line shape without changing a movement direction of a laser, manufacturing processes may be simplified and manufacturing time may be decreased. This will be described below in further detail with reference to a method of manufacturing the solar cell 150. However, the disclosure is not limited to the above examples and the openings 22a may have various planar shapes.

FIG. 4 illustrates that the finger electrode 24a is also formed in the bus bar electrode 24b and thus the electrode parts 240 are connected to each other by the finger electrode 24a. However, the disclosure is not limited to the above example and the finger electrode 24a may not be formed in the bus bar electrode 24b.

In this regard, a pitch P4 between the electrode parts 240 may be larger than a width W4 of each of the electrode parts 240. Thus, the anti-reflective film 22, which is an insulating film, may be exposed between the electrode parts 240.

In this regard, the electrode parts 240 of the bus bar electrode 24b may be arranged so as to have a uniform width W4 and a uniform pitch P4. Accordingly, the anti-reflective film 22 may be exposed so as to have a uniform width and a uniform pitch and thus be adhered to the conductive film 142. In such configuration, adhesions to the conductive film 142 are periodically formed and, accordingly, adhesion uniformity may be enhanced. However, the disclosure is not limited to the above examples and width, pitch, and the like of the electrode parts 240 may be variously changed. This will be described below with reference to FIG. 7.

In the present embodiment, the bus bar electrode 24 includes the electrode parts 240 and thus the anti-reflective film 22 is exposed between the electrode parts 240. Accordingly, the anti-reflective film 22 and the conductive film 142 are adhered between the electrode parts 240. Thus, adhesive strength of the conductive film 142 may be enhanced due to excellent adhesion between the anti-reflective film 22 and the conductive film 142. This will be described below in more detail.

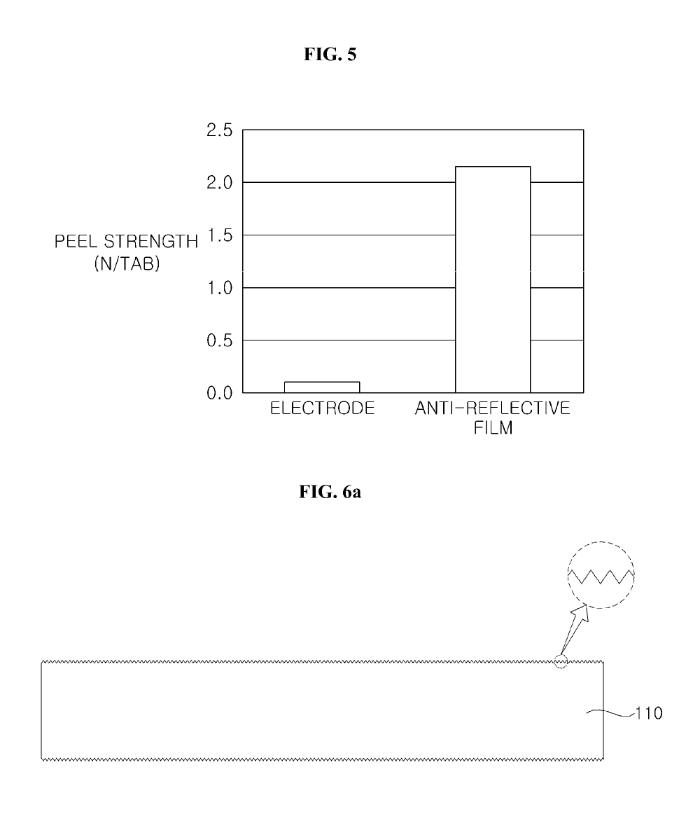

The conductive film 142 has relatively low adhesion to the first electrode 24 formed by plating, while having excellent adhesion to the anti-reflective film 22. This will be described below in further detail with reference to FIG. 5.

FIG. 5 is a graph showing measurement results of peel strength between an electrode and a conductive film and peel strength between an anti-reflective film formed of silicon nitride and the conductive film. In this regard, the electrode includes a seed layer including Ni and a plating layer including Cu, a peeling angle is 90 degrees, and a peel rate is 50 mm/min. Referring to FIG. 5, it can be confirmed that the peel strength between the electrode and the conductive film is very low, while the peel strength between the anti-reflective film and the conductive film is very high. That is, it can be confirmed that, when a conductive film is attached only to an electrode, adhesion characteristics are poor.

In the present embodiment, the conductive film 142 adhered to the bus bar electrode 24b and thus electrically connected thereto is also adhered to (e.g., contact) the anti-reflective film 22 exposed between the electrode parts 240 of the bus bar electrode 24b. Accordingly, adhesion to the conductive film 142 may be enhanced due to excellent adhesion between the anti-reflective film 22 and the conductive film 142. Thus, occurrence of cracks between the semiconductor substrate 110 and the first electrode 24 may be prevented and, consequently, separation of the first electrode 24 may be prevented. As a result, packing density of the solar cell 150 may be enhanced and adhesion to the conductive film 142 may be enhanced.

In addition, in the present embodiment, the first portions 20a are formed only in regions corresponding to the electrode parts 240, not in a total outer area of the bus bar electrode 24b, and thus, the area of the first portions 20a may be minimized. That is, an open circuit voltage of the solar cell 150 may be enhanced by minimizing the area of the first portions 20a doped at a relatively high concentration.

Moreover, in the present embodiment, the conductive film 142 and the anti-reflective film 22 may also be adhered to each other at an outer side of the bus bar electrode 24b by forming the width W3 of the conductive film 142 to be larger than the outer width W2 of the bus bar electrode 24b. Thus, the adhesive strength of the conductive film 142 may be further enhanced by further increasing an adhesion area between the conductive film 142 and the anti-reflective film 22. However, the disclosure is not limited to the above examples and the width W3 of the conductive film 142 may be the same or smaller than the outer width W2 of the bus bar electrode 24b.

For example, a ratio of an exposed area of the anti-reflective film 22 to the total outer area (the sum of the area of the outermost two of the electrode parts 240 and the area of another of the electrode parts 240 disposed between the outermost two) of the bus bar electrode 24b at portions in which the bus bar electrode 24b and the conductive film 142 overlap with each other may be 0.2 or greater. When the ratio is less than 0.2, effects of enhancing the adhesion strength of the conductive film 142 may be small. Further considering the adhesive strength of the conductive film 142, the ratio may be 0.4 or greater. In this regard, an upper limit of the ratio is not particularly limited. However, considering electrical conductivity and the like, the ratio may be 0.9 or less (e.g., 0.85 or less).

In addition, a ratio of an exposed area of the anti-reflective film 22 to a total area of the conductive film 142 may be 0.2 or greater. Further considering the adhesive strength of the conductive film 142, the ratio may be 0.3 or greater. In this regard, an upper limit of the ratio is not particularly limited, but, the ratio may be 0.95 or less (e.g., 0.9 or less) in consideration of the fact that, when the width of the conductive film 142 increases, raw material costs and the like may be increased.

The structure of the first electrode 24 will now be described in further detail with reference to FIG. 3. Referring to an enlarged circle of FIG. 3, the first electrode 24 may have a structure in which a plurality of layers is stacked. For example, the first electrode 24 may include a seed layer 242, a plating layer 244, and a capping layer 246 that are sequentially stacked on the emitter region 20 (the back surface field region 30 in the case of the second electrode 34), which is a conductive type region. That is, the finger electrodes 24a and the bus bar electrode 24b including the electrode parts 240, constituting the first electrode 24, may include the seed layer 242, the plating layer 244, and the capping layer 246.

In this regard, the seed layer 242 is formed to easily form the plating layer 244. More particularly, it is difficult to directly form the plating layer 224 on the semiconductor substrate 110 including silicon, and thus, the seed layer 242 is formed using a material that has high reactivity with silicon and thus may be easily formed on silicon and thereafter the plating layer 244 is formed. For example, the seed layer 242 may include a metal such as nickel (Ni), platinum (Pt), titanium (Ti), cobalt (Co), tungsten (W), molybdenum (Mo), tantalum (Ta), or an alloy thereof. Thus, silicon of the semiconductor substrate 110 reacts with the metal of the seed layer 242 at an interface between the semiconductor substrate 110 and the seed layer 242 and, as a result, a silicide layer (not shown) (e.g., NiSi, NiSi₂, PtSi, Co₂Si, CoSi, CoSi₂, WSi₂, MoSi₂, or TaSi₂) may be formed. For example, a NiSi layer having low contact resistance with silicon, high adhesion, and low thermal stress thus having excellent thermal stability may be formed. In this case, the seed layer 242 may include Ni.

The seed layer 242 may also be formed in the openings 22a formed in the anti-reflective film 22, which is an insulating film, and thus contact the emitter region 20.

The plating layer 244 formed on the seed layer 242 may be formed of a metal material having high electrical conductivity. The plating layer 244 has the largest thickness among the other layers of the first electrode 24 and thus may include a material that has high electrical conductivity and is inexpensive. For example, the plating layer 244 may include Cu. However, the disclosure is not limited to the above examples and the plating layer 244 may include a material such as Cu, Ag, Au, or an alloy thereof.

The plating layer 244 may have a greater thickness than the seed layer 242 or the capping layer 246. In addition, the plating layer 244 has a large width and thus may be formed on the seed layer 242 and also on the anti-reflective film 22 adjacent to opposite sides of the seed layer 242. Such configuration is formed through lateral growth when the plating layer 244 is formed by plating or the like. However, the disclosure is not limited to the above example.

The capping layer 246 may be formed on the plating layer 244 so as to cover the plating layer 244 and to protect the plating layer 244 from oxidation or corrosion. The capping layer 246 may include tin (Sn), Ag, or an alloy thereof.

In FIG. 3 and the description thereof, each of the seed layer 242 and the plating layer 244 and the capping layer 246 that are formed on the seed layer 242 is formed as a single layer, but may include at least two layers. In addition, the plating layer 244 and the capping layer 246 may include the same material thus being formed as a single layer. As such, at least one metal layer may be formed on the seed layer 242.

Hereinafter, the stacked structure of the electrode parts 240 constituting the bus bar electrode 24b will be described. The seed layers 242 of the respective electrode parts 240 are connected to the emitter region 20, which is an impurity region, via the openings 22a formed in the anti-reflective film 22 and also partially formed in an upper portion of the anti-reflective film 22. The plating layer 244 and the capping layer 244 of each electrode part 240 are formed on the seed layer 242 and a portion of the anti-reflective film 22 in the vicinity of the seed layer 242, and the anti-reflective film 22 is exposed between adjacent electrode parts 240.

The widths of the seed layer 242 and the plating layer 244, the pitch of the electrode parts 240, the outer width W2 of the bus bar electrode 24b, and the like may vary according to size of the semiconductor substrate 110, design difference, and the like. Thus, the disclosure is not limited to these values. However, as an example only, a width W5 of the seed layer 242 may be 10 μm to 20 μm, a width W6 of the plating layer 244 and the width W4 of the electrode part 240 may be 30 μm to 50 μm, and a pitch P4 of the electrode parts 240 may be 50 μm to 200 μm. In addition, the outer width W2 of the bus bar electrode 24b may be 0.8 mm to 2 mm. The width of each opening 22a may be substantially similar to the width W5 of the seed layer 242 and thus may be 10 μm to 20 μm. These ranges are provided for illustrative purposes only in consideration of electrical conductivity, adhesion to the conductive film 142, and the like and the disclosure is not limited thereto.

According to the present embodiment, the anti-reflective film 22 is disposed at an inner side and/or an outer side of the bus bar electrode 24b (i.e., between the electrode parts 240 and at outer sides of the electrode parts 240), and thus, adhesion to the conductive film 142 may be enhanced.

In addition, the bus bar electrode 24b includes the electrode parts 240 separated from each other and thus a total area of the bus bar electrode 24b may be reduced. Accordingly, the number of process for forming the openings 22a in the anti-reflective film 22 may be reduced and raw material costs for formation of the bus bar electrode 24b may be reduced.

For example, when the pitch of the electrode parts 240 of the bus bar electrode 24b is 30 μm, the bus bar electrode 24b is formed to entirely cover the anti-reflective film 22 by forming the seed layer 242 to a width of 10 μm and forming the plating layer 244 (or the electrode part 240) to a width of 30 μm. In this case, when the bus bar electrode 24b has a width of 1 mm, the number of the electrode parts 240 needed is 34. By contrast, as in the present embodiment, when the pitch of the electrode parts 240 of the bus bar electrode 24b is increased to 50 μm, 100 μm, or 200 μm while the widths of the seed layer 242 and the plating layer 244 are kept, the number of the electrode parts 240 needed is decreased to 21, 11, or 6. As such, the number of the electrode parts 240 may be reduced.

Accordingly, the areas of the first portions 20a and 30a, which are high-concentration portions, may be reduced and, consequently, an open circuit voltage of the solar cell 150 may be increased. For example, when the pitch of the electrode parts 240 is 200 μm, the solar cell 150 may have a high open circuit voltage of approximately 3 to 4 mV when compared to a case in which the pitch of the electrode parts 240 is 30 μm.

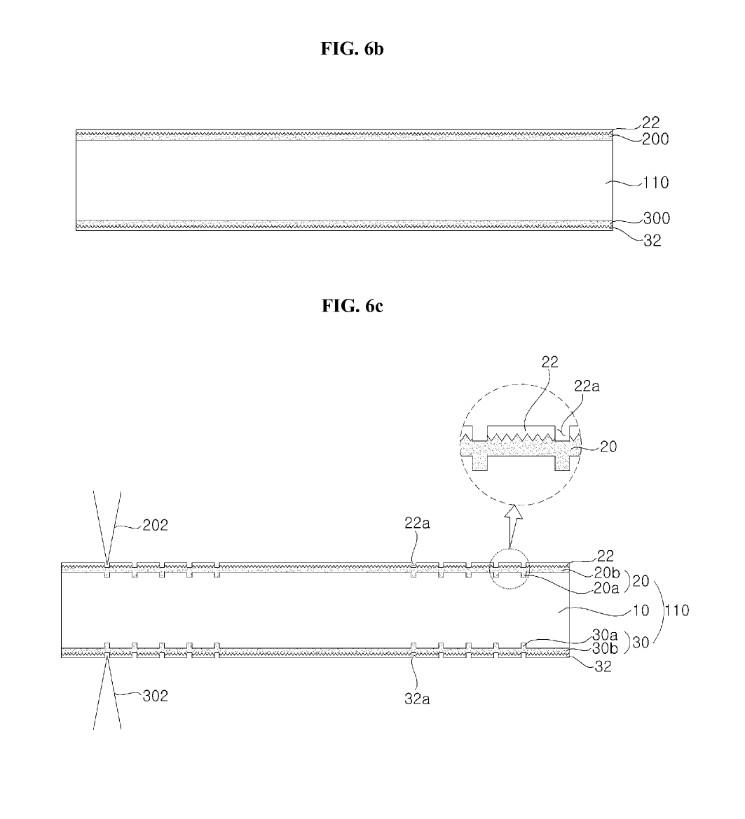

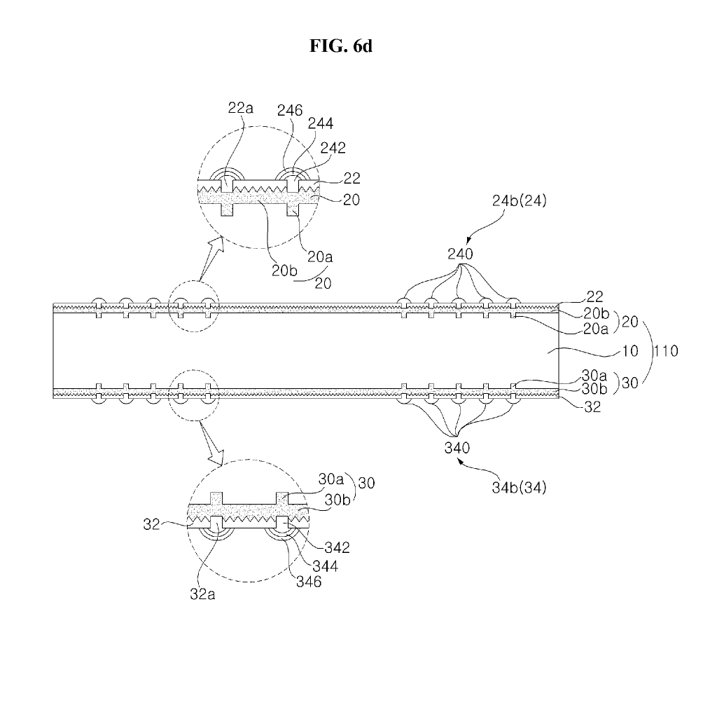

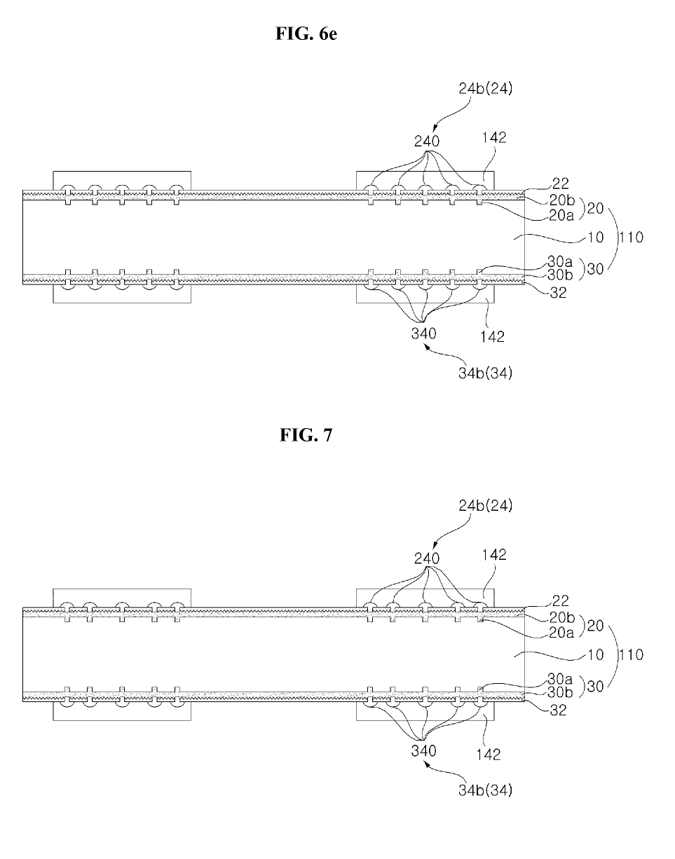

Hereinafter, a method of manufacturing the solar cell 150 according to the embodiment of the present invention will be described in detail with reference to FIGS. 6A to 6E. A detailed description of elements that have already been described will be omitted herein and a detailed description will be provided only for elements that have not been described herein.

FIGS. 6A to 6E are sectional views illustrating a solar cell manufacturing method according to an embodiment of the present invention.

First, as illustrated in FIG. 6A, the semiconductor substrate 110 of a second conductive type is prepared. At least one of a front surface and a back surface of the semiconductor substrate 110 may be textured to have an uneven portion. The texturing process may be wet texturing or dry texturing. Wet texturing may be performed by immersing the semiconductor substrate 110 in a texturing solution and is advantageous in that manufacturing time is short. Dry texturing is carried out by cutting a surface of the semiconductor substrate 110 using a diamond drill, a laser or the like. In dry texturing, irregularities may be uniformly formed, while manufacturing time is long and damage to the semiconductor substrate 110 may occur. As such, the semiconductor substrate 110 may be textured using various methods.

Subsequently, as illustrated in FIG. 6B, impurity formation layers 200 and 300, the anti-reflective film 22, and the passivation film 32 are formed at the semiconductor substrate 110.

In particular, the impurity formation layer 200 may be formed at the front surface of the semiconductor substrate 110 through doping with a first conductive type impurity, and the impurity formation layer 300 may be formed at the back surface of the semiconductor substrate 110 through doping with a second conductive type impurity.

The first or second conductive type impurity may be doped by various methods such as thermal diffusion, ion implantation, or the like.

Thermal diffusion is a process whereby a first or second conductive type impurity is doped by diffusing a gas compound (e.g., BBr₃) of the first or second conductive type impurity into the semiconductor substrate 110 in a state in which the semiconductor substrate 110 is heated. This method is advantageous in that manufacturing processes are simple and manufacturing costs are low.

Ion implantation is a method in which a first conductive type impurity is doped by ion implantation, followed by activated heat treatment. More particularly, after ion implantation, the semiconductor substrate 110 is damaged or broken and thus plural lattice defects and the like are formed and thus mobility of electrons or holes is reduced, and the ion-implanted impurity is not positioned at a lattice position and thus inactivated. Thus, the ion-implanted impurity is activated through activated heat treatment. In ion implantation, doping in a lateral direction may be reduced and thus a degree of integration may be increased and concentration may be easily adjusted. In addition, ion implantation is a doping method in which doping is implemented only on a desired surface and thus may be easily applied to a case in which the front and back surfaces of the semiconductor substrate 110 are doped with different impurities.

The impurity formation layers 200 and 300 are formed so as to have an entirely uniform doping concentration and thus may have an entirely uniform resistance.

In addition, after forming the impurity formation layer 200, the anti-reflective film 22 is formed thereon and, after forming the impurity formation layer 300, the passivation film 32 is formed thereon. The anti-reflective film 22 and the passivation film 32 may be formed by various methods such as vacuum deposition, chemical vapor deposition, spin coating, screen-printing, spray coating, or the like.

In this regard, the order of manufacturing processes may be variously changed so long as the impurity formation layer 200 and the anti-reflective film 22 are sequentially formed at the front surface of the semiconductor substrate 110 and the back surface field region 30 and the passivation film 32 are sequentially formed at the back surface of the semiconductor substrate 110.

That is, the impurity formation layer 200 and the anti-reflective film 22 may be sequentially formed at the front surface of the semiconductor substrate 110, and thereafter the impurity formation layer 300 and the passivation film 32 may be formed at the back surface of the semiconductor substrate 110. In another embodiment, the impurity formation layer 300 and the passivation film 32 may be formed at the back surface of the semiconductor substrate 110 and thereafter the impurity formation layer 200 and the anti-reflective film 22 may be sequentially formed at the front surface of the semiconductor substrate 110.

In another embodiment, the impurity formation layers 200 and 300 may be simultaneously or sequentially formed respectively at the front and back surfaces of the semiconductor substrate 110. Thereafter, the anti-reflective film 22 and the passivation film 32 may be simultaneously or sequentially formed.

The impurity formation layers 200 and 300, the anti-reflective film 22, and the passivation film 32 may be formed according to various other manufacturing sequences.

In addition, in the present embodiment, the impurity formation layers 200 and 300, which have different conductive types, are formed before the first electrode 24 and/or the second electrode 34. However, the disclosure is not limited to the above examples. That is, only at least one (e.g., the impurity formation layer 200) of the impurity formation layers 200 and 300 may be formed before the first electrode 24 and/or the second electrode 34. Another of the impurity formation layers 200 and 300 may be formed through diffusion or the like of a material included in the first electrode 24 and/or the second electrode while forming the first electrode 24 and/or the second electrode.

Subsequently, as illustrated in FIG. 6C, the openings 22a and 32a are respectively formed in the anti-reflective film 22 and the passivation film 32 by selectively heating the anti-reflective film 22 and the passivation film 32. The openings 22a and 32a are formed to respectively correspond to the finger electrodes 24a and 34a (see FIG. 6E) and the electrode parts 240 and 340 of the bus bar electrodes 24b and 34b (see FIG. 6E) of the first and second electrodes 24 and 34.

To form the openings 22a and 32a, various methods for selectively heating the anti-reflective film 22 and the passivation film 32 may be used. For example, lasers 202 and 302 may be used. That is, the openings 22a and 32a may be formed by laser ablation. In the present embodiment, various lasers may be used as the lasers 202 and 302. For example, an Nd—YVO₄ laser may be used.

As such, in a process of forming the openings 22a and 32a, a first or second conductive impurity may further be doped into portions corresponding to the openings 22a and 34a to form the first portions 20a and 30a at the portions corresponding to the openings 22a and 34a. In this regard, the second portions 20b and 30b are formed at the remaining portions.

For example, the first or second conductive type impurity may further be doped using a laser doping selective emitter (LDSE) method. That is, the anti-reflective film 22 and the passivation film 32 may be formed, separate layers for doping may be formed thereon, and then dopants included in the separate layers may be diffused into the semiconductor substrate 110 by irradiating the layers with laser beams from the lasers 202 and 302, respectively. However, the disclosure is not limited to the above examples and various methods such as a process in which the openings 22a and 22b are formed, followed by further doping with a first or second conductive type impurity, and the like may be used.

As such, when the first portions 20a and 30a are formed together when respectively forming the openings 22a and 32a in the anti-reflective film 22 and the passivation film 32, the first portions 20a and 30a and the openings 22a and 32a are formed at the same corresponding positions. The openings 22a and 32a are portions in which the electrodes parts 240 and 340 are to be respectively formed and thus the electrode parts 240 and 340 of the bus bar electrodes 24b and 34b, formed in the openings 22a and 32a, may be accurately aligned respectively with respect to the first portions 20a and 30a.

In addition, the uneven portions (uneven portions by texturing) formed at portions at which the openings 22a and 32a are formed may be broken by laser ablation. Thus, the uneven portions formed inside the openings 22a and 32a by texturing may be removed.

In the present embodiment, the openings 22a and 32a are formed using the lasers 202 and 302, respectively, but the disclosure is not limited thereto. Thus, the openings 22a and 32a may be formed by various other methods. In this case, the openings 22a and 32a may have various shapes other than the line shape.

Subsequently, as illustrated in FIG. 6D, the first electrodes 24 electrically connected to the emitter region 20 and the second electrodes 34 electrically connected to the back surface field region 30 (or the semiconductor substrate 110) are formed.

The first and second electrodes 24 and 34 may be formed respectively in the openings 22a and 32a formed respectively in the anti-reflective film 22 and the passivation film 32 by various methods such as plating, deposition, or the like. More particularly, the seed layers 242 and 342 are formed in the openings 22a and 32a by plating or deposition and then the plating layers 244 and 344 are formed on the seed layers 242 and 342 by plating. In addition, the capping layers 246 and 346 may further be formed on the plating layers 244 and 344 by plating or deposition.

Consequently, the electrodes parts 240 or 340 of the bus bar electrode 24b or 34b are separated from each other and thus the anti-reflective film 22 or the passivation film 32, which is an insulating film, is exposed therebetween.

In the above-described embodiment, the first and second electrodes 24 and 34 are formed by plating or the like. However, the disclosure is not limited to the above examples. Thus, only at least one of the first and second electrodes 24 and 34 may be formed using the above-described manufacturing processes to have the above-described structure, and another thereof may be formed by fire through, laser firing contact, or the like using a paste.

Subsequently, as illustrated in FIG. 6E, the conductive film 142 is adhered to each of the bus bar electrodes 24b and 34b. That is, the conductive film 142 is positioned on the first electrode 24 and then thermally pressed, and the corresponding conductive film 142 is positioned on the second electrode 34 of the adjacent solar cell 150 and then thermally pressed. The conductive film 142 may be formed by dispersing conductive particles formed of Au, Ag, Ni, Cu, or the like, which are highly conductive, in a film formed of epoxy resin, acryl resin, polyimide resin, polycarbonate resin, or the like. When the conductive film 142 is pressed by heat in a state of being positioned on each of the bus bar electrodes 24b and 34b, conductive particles are exposed outside of the conductive film 142 and the conductive film 142 and each of the bus bar electrodes 24b and 34b may be electrically connected by the exposed conductive particles. In this regard, the anti-reflective film 22 or the passivation film 32 is exposed between the electrode parts 240 constituting the bus bar electrode 24b or between the electrode parts 340 constituting the bus bar electrode 34b and at outer sides of the bus bar electrode 24b or 34b, thus being adhered to the conductive film 142. Accordingly, adhesion to the conductive film 142 may be enhanced.

Hereinafter, a solar cell according to another embodiment of the present invention will be described in detail with reference to FIG. 7. A detailed description of the same or almost the same elements as those in the previous embodiment will be omitted herein and a detailed description will be provided only for different elements herein.

FIG. 7 is a sectional view of a solar cell according to another embodiment of the present invention.

Referring to FIG. 7, in the solar cell according to the present embodiment, the electrode parts 240 of the bus bar electrode 24b and the electrode parts 340 of the bus bar electrode 34b may be arranged so as to have different pitches. For example, the electrode parts 240 or 340 may be separated from each other such that the electrode parts 240 or 340 have a smaller pitch at edge portions than at a central portion. As such an example, the pitch of the electrode parts 240 or 340 may gradually decrease towards the edge portions from the central portion.

Accordingly, an adhesion area between the conductive film 142 and an insulating film (i.e., the anti-reflective film 22 or the passivation film 32) may be sufficiently secured at the central portion of each of the bus bar electrodes 24b and 34b. In this regard, when forming the width of the conductive film 142 to be greater than the outer width of each of the bus bar electrodes 24b and 34b, the adhesion area between the conductive film 142 and the insulating film may be sufficiently secured even at the edge portions of the bus bar electrode 24b and 34b. Thus, adhesion to the conductive film 142 may further be enhanced by sufficiently securing the adhesion area between the conductive film 142 and the insulating film at the central portion and the edge portions. In addition, various modifications are possible.

According to the present embodiment, the insulating film is disposed inside and/or outer sides of a bus bar electrode (i.e., between electrode parts and outer sides of the electrode parts) and, accordingly, adhesion between the bus bar electrode and a conductive film may be enhanced.

In addition, the bus bar electrode includes a plurality of electrode parts separated from each other and thus a total area of the bus bar electrode may be reduced. Accordingly, the number of processes for forming openings in an anti-reflective film may be reduced and raw material costs for formation of the bus bar electrode may be reduced. In addition, high-concentration portions are formed in only portions corresponding to the openings and thus an area of the high-concentration portions may be reduced and, accordingly, an open circuit voltage may be enhanced. That is, efficiency and productivity of a solar cell may be enhanced.

Particular features, structures, or characteristics described in connection with the embodiment are included in at least one embodiment of the present disclosure and not necessarily in all embodiments. Furthermore, the particular features, structures, or characteristics of any specific embodiment of the present disclosure may be combined in any suitable manner with one or more other embodiments or may be changed by those skilled in the art to which the embodiments pertain. Therefore, it is to be understood that contents associated with such combination or change fall within the spirit and scope of the present disclosure.

Although embodiments have been described with reference to a number of illustrative embodiments, it should be understood that numerous other modifications and applications may be devised by those skilled in the art that will fall within the intrinsic aspects of the embodiments. More particularly, various variations and modifications are possible in concrete constituent elements of the embodiments. In addition, it is to be understood that differences relevant to the variations and modifications fall within the spirit and scope of the present disclosure defined in the appended claims.

What is claimed is:

1. A solar cell comprising:
a substrate;
a conductive type region formed at the substrate;
an insulating film formed on the conductive type region; and
an electrode electrically connected to the conductive type region through the insulating film,
wherein the electrode comprises a plurality of finger electrodes and at least one bus bar electrode formed in a direction crossing the finger electrodes,
wherein the bus bar electrode comprises a plurality of electrode parts separated from each other, and
wherein the insulating film comprises a plurality of openings corresponding to the electrode parts to be exposed between the electrode parts at a portion at which the bus bar electrode is disposed.

2. The solar cell according to claim 1, wherein the electrode parts comprise seed layers electrically connected to the conductive type region via the openings of the insulating film and plating layers disposed at least on the seed layers.

3. The solar cell according to claim 1, wherein a pitch between the electrode parts is larger than a width of each of the electrode parts.

4. The solar cell according to claim 3, wherein the width of each of the electrode parts is 30 μm to 50 μm, and the pitch between the electrode parts is 50 μm to 200 μm.

5. The solar cell according to claim 2, wherein each of the seed layers of the electrode parts has a width of 10 μm to 20 μm, and each of the plating layers has a width of 30 μm to 50 μm.

6. The solar cell according to claim 1, wherein the electrode parts have a stripe shape.

7. The solar cell according to claim 1, wherein a ratio of an exposed area of the insulating film to an outer area of the bus bar electrode at a portion at which the bus bar electrode is disposed is 0.2 to 0.9.

8. The solar cell according to claim 7, wherein the ratio is 0.4 to 0.85.

9. The solar cell according to claim 1, further comprising a conductive film adhered to an upper portion of the bus bar electrode,
wherein the conductive film has a width that is larger than an outer width of the bus bar electrode.

10. The solar cell according to claim 9, wherein a ratio of an area of the insulating film adhered to the conductive film to an area of the conductive film is 0.2 to 0.95.

11. The solar cell according to claim 10, wherein the ratio is 0.3 to 0.9.

12. The solar cell according to claim 1, further comprising a conductive film adhered to the bus bar electrode and the insulating film.

13. The solar cell according to claim 1, wherein the electrode parts are separated from each other to have a smaller pitch at edge portions than at a central portion.

14. The solar cell according to claim 1, wherein the conductive type region comprises a first portion corresponding to the electrode parts and a second portion having a higher resistance than the first portion.

15. The solar cell according to claim 14, wherein the second portion is disposed to correspond to a portion in which the electrode is not formed and to a portion of the insulating film disposed between the electrode parts of the bus bar electrode.

16. The solar cell according to claim 1, wherein adhesion between the conductive film and the insulating film is higher than adhesion between the conductive film and the electrode.

17. The solar cell according to claim 16, wherein the insulating film comprises a silicon nitride film.

18. A method of manufacturing a solar cell, the method comprising:
preparing a substrate;
forming a conductive type region at the substrate;
forming an insulating film on the conductive type region;
forming a plurality of openings separated from each other in the insulating film to correspond to a bus bar electrode; and
forming the bus bar electrode by forming a plurality of electrode parts electrically connected to the conductive type region via the openings formed in the insulating film,
wherein the insulating film is exposed between the electrode parts.

19. The method according to claim 18, wherein the openings are formed using a laser.

20. The method according to claim 18, further comprising connecting the bus bar electrode and a conductive film by positioning the conductive film on the bus bar electrode and performing heat pressing thereon,
wherein the conductive film is adhered to the electrode parts and the insulating film exposed between the electrode parts.
